(19) United States
(12) Patent Application Publication
(10) Pub. No.: US 2006/0044765 A1
(43) Pub. Date: Mar. 2, 2006

(54) Heat dissipation device

(75) Inventor: Bai-Shiou Chen, Taipei (TW)

Correspondence Address: TROXELL LAW OFFICE PLLC, SUITE 1404, 5205 LEESBURG PIKE, FALLS CHURCH, VA, 22041, US

(73) Assignee: Infowize Technologies Corporation

(21) Appl. No.: 10/930,788

(22) Filed: Sep. 1, 2004

(51) Int. Cl. H05K 7/20

(52) U.S. Cl. 361/720

(57) ABSTRACT

A heat dissipation device of a PCB has electronic devices arranged thereon. The heat dissipation device has a plurality of heat dissipation holes formed on the PCB and corresponding to the electronic devices, respectively. The heat dissipation device can dissipate heat from an electronic device without a fan, so that a restriction of an arrangement of the electronic device on the PCB can be prevented.

### BACKGROUND OF THE INVENTION

1. Field of the Invention

The present invention relates to a heat dissipation-device, and particularly relates to a heat dissipation device that can dissipate heat from an electronic device, like an IC or a socket disposed on a PCB, without a fan, so that restriction of an arrangement of the electronic device on the PCB can be prevented.

2. Background of the Invention

As computer industries develop, the data-processing rate of an electronic device, such as an IC, increases, and more heat is generated thereby. For easy operation of this electronic device in a normal temperature, a fan or a heat dissipation device can be provided for sinking heat.

Referring to FIG. 1, a conventional heat dissipation device 9 operates with a fan 91 arranged on a PCB 5. A heat pipe 92 transmits heat from an electronic device 6 to the fan 91 so as to exhaust the heat via the fan 91.

If there are some other electronic devices 7, 8 arranged on the PCB 5, the other electronic devices 7, 8 must be adjacent to the fan 91 for simultaneous heat transfer. Therefore, the electronic devices 6, 7, 8 will be restricted and cannot be arranged in a proper manner. If an additional heat pipe is added to transmit the electronic devices 6, 7, 8 via the fan 91, costs thereof will increase.

Hence, an improvement over the prior art is required to overcome the disadvantages thereof.

### SUMMARY OF INVENTION

The primary object of the invention is therefore to specify a heat dissipation device that can dissipate heat from an electronic device without a fan, so that a restriction of an arrangement of the electronic device on the PCB can be prevented.

According to the invention, the object is achieved by a heat dissipation device used for a PCB that has electronic devices arranged thereon. The heat dissipation device has a plurality of heat dissipation holes formed in the PCB and corresponding to the electronic devices, respectively.

To provide a further understanding of the invention, the following detailed description illustrates embodiments and examples of the invention. Examples of the more important features of the invention thus have been summarized rather broadly in order that the detailed description thereof that follows may be better understood, and in order that the contributions to the art may be appreciated. There are, of course, additional features of the invention that will be described hereinafter and which will form the subject of the claims appended hereto.

### BRIEF DESCRIPTION OF THE DRAWINGS

These and other features, aspects, and advantages of the present invention will become better understood with regard to the following description, appended claims, and accompanying drawings, where:

FIG. 1 is a perspective view of a conventional heat dissipation device;

FIG. 2 is a perspective view of a heat dissipation device of a first embodiment according to the present invention;

FIG. 3 is a cross-sectional profile of the heat dissipation device of the first embodiment according to the present invention;

FIG. 4 is a cross-sectional profile of the heat dissipation device of a second embodiment according to the present invention;

FIG. 5 is a cross-sectional profile of the heat dissipation device of a third embodiment according to the present invention; and

FIG. 6 is a cross-sectional profile of the heat dissipation device of a fourth embodiment according to the present invention.

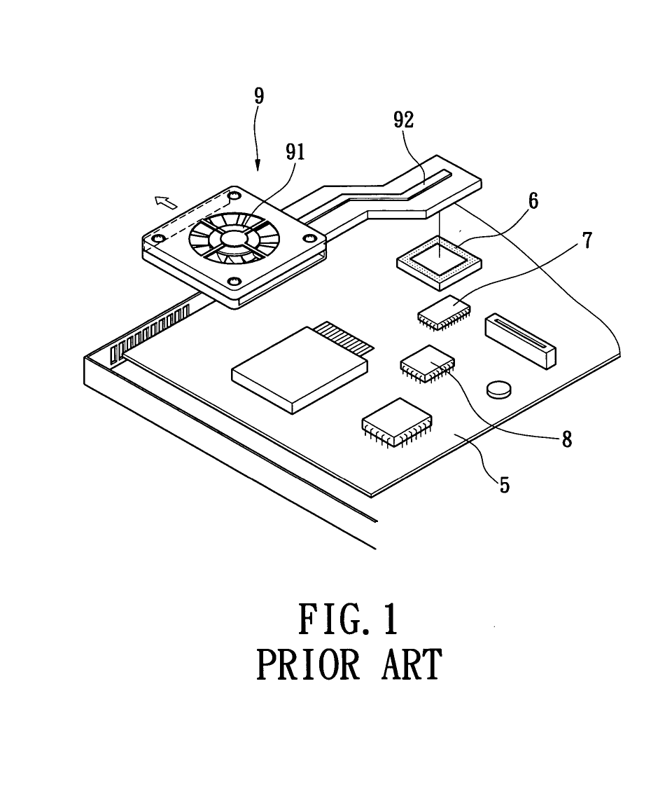

### DETAILED DESCRIPTION OF THE EMBODIMENTS

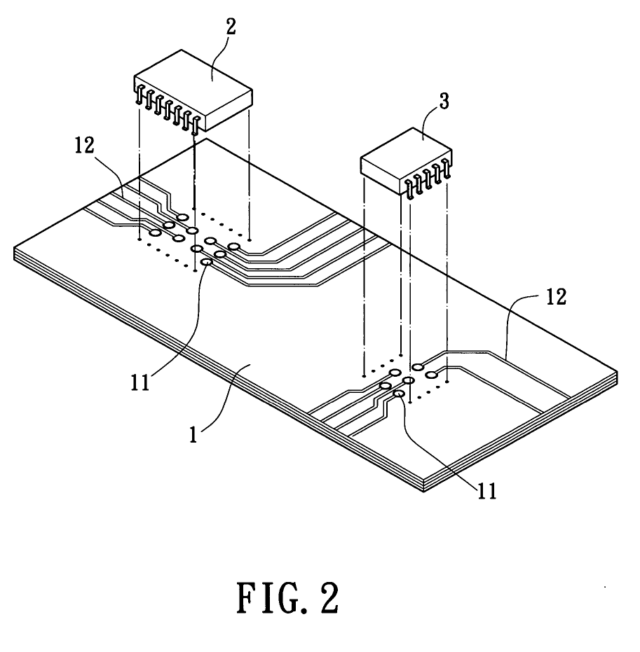

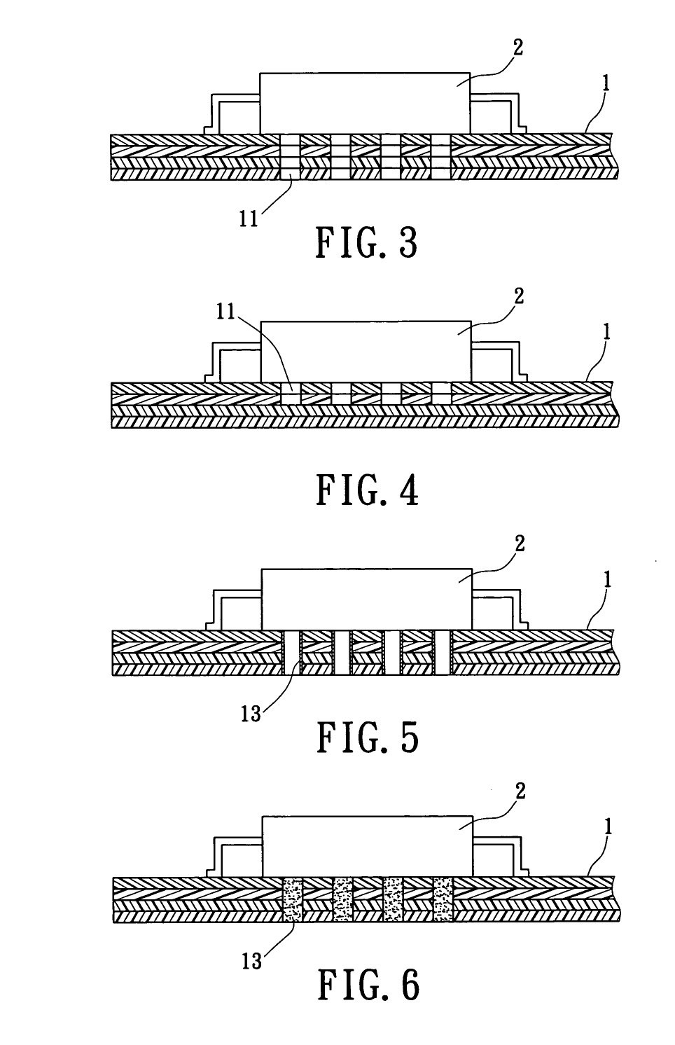

With respect to FIGS. 2 and 3, a heat dissipation device adopted for a PCB 1 includes a plurality of electronic devices 2, 3, comprising a plurality of heat dissipation holes 11 formed in the PCB 1 and corresponding to the electronic devices 2, 3, respectively. A respective one of the electronic devices may be an IC or a socket. The PCB may be a multilayered PCB or a single-layer PCB. In this preferred embodiment, the PCB 1 is a multilayered PCB.

The heat dissipation holes 11 are formed beneath or surrounding the electronic devices 2, 3, respectively. The heat dissipation holes 11 are, for example, round. The heat dissipation holes 11 are through holes that penetrate an upper surface towards a lower surface of the PCB 1 (in FIG. 3), or are concave from the upper surface of the PCB but do not penetrate therethrough (in FIG. 4). The heat dissipation holes 11 provide heat dissipation from the electronic devices 2, 3 via heat radiation and heat convection. A plurality of heat-conducting lines 12 connects the heat dissipation holes. The heat-conducting lines 12 are made of metallic materials with good heat conductivities, like a copper or a tin, and are arranged on the PCB 1. The heat-conducting lines 12 can be arranged on the upper surface of the PCB 1, the lower surface of the PCB 1, or different layers of the PCB 1; The heat-conducting lines 12 can connect to one another or be disconnected from one another, and each of the heat-conducting lines 12 has an end extending towards an edge of the PCB 1 to transmit heat to the edge of the PCB 1.

The heat dissipation device further includes a heat conductor 13 arranged in each of the heat dissipation holes 11 (in FIGS. 5 and 6). The heat conductor 13 is made of good conductive materials, such as copper or conductive glue. The heat conductor 13 can be arranged on an inner wall of each of the heat dissipation holes 11 (in FIG. 5). The heat conductor 13 can be filled with each of the heat dissipation holes 11 (in FIG. 6). According to these embodiments, the heat conductor 13 can enclose each of the heat dissipation holes 11 to provide a heat convention.

Advantages of the present invention are summarized as follows:
1. The heat dissipation holes 11 can be processed extremely simply for chip manufactures.
2. The heat-conducting lines 12 can transmit the heat away from the electronic devices 2, 3 by the extension thereof to the edge of the PCB 1 to provide improved heat dissipation efficiency.
3. The heat dissipation device can pass heat away without fans, allowing various arrangements of the electronic devices 2, 3 on the PCB 1 can be.

It should be apparent to those skilled in the art that the above description is only illustrative of specific embodiments and examples of the invention. The invention should therefore cover various modifications and variations made to the herein-described structure and operations of the invention, provided they fall within the scope of the invention as defined in the following appended claims.

What is claimed is:

1. A heat dissipation device adopted for a PCB having a plurality of electronic devices, comprising a plurality of heat dissipation holes formed in the PCB and corresponding to the electronic devices, respectively.

2. The heat dissipation device as claimed in claim 1, wherein the PCB is a multilayered PCB.

3. The heat dissipation device as claimed in claim 1, wherein the PCB is a single-layer PCB.

4. The heat dissipation device as claimed in claim 1, wherein the heat dissipation holes are formed beneath the electronic devices, respectively.

5. The heat dissipation device as claimed in claim 1, wherein the heat dissipation holes are formed surrounding the electronic devices, respectively.

6. The heat dissipation device as claimed in claim 1, wherein the heat dissipation holes are through holes penetrating the PCB.

7. The heat dissipation device as claimed in claim 1, wherein the heat dissipation holes are concave from the PCB.

8. The heat dissipation device as claimed in claim 1, further including a heat conductor arranged on an inner wall of each of the heat dissipation holes.

9. The heat dissipation device as claimed in claim 1, further including a heat conductor filled with each of the heat dissipation holes.

10. The heat dissipation device as claimed in claim 1, further including a plurality of heat-conducting lines connecting the heat dissipation holes, wherein the heat-conducting lines are arranged on the PCB.

11. The heat dissipation device as claimed in claim 10, wherein the heat-conducting lines are made of metallic materials with good heat conductivities.

12. The heat dissipation device as claimed in claim 10, wherein the heat-conducting lines are arranged on an upper surface of the PCB.

13. The heat dissipation device as claimed in claim 10, wherein the heat-conducting lines are arranged on a lower surface of the PCB.

14. The heat dissipation device as claimed in claim 10, wherein the heat-conducting lines are arranged on different layers of the PCB.

15. The heat dissipation device as claimed in claim 10, wherein the heat-conducting lines connect to one another.

16. The heat dissipation device as claimed in claim 10, wherein the heat-conducting lines fail to connect to one another.

17. The heat dissipation device as claimed in claim 10, wherein each of the heat-conducting lines has an end extending towards an edge of the PCB.

18. The heat dissipation device as claimed in claim 10, wherein a respective one of the electronic devices is an IC.

19. The heat dissipation device as claimed in claim 10, wherein a respective one of the electronic devices is a socket.
